(19) United States
(12) Patent Application Publication
(10) Pub. No.: US 2020/0089041 A1
(43) Pub. Date: Mar. 19, 2020

(54) FULL DISPLAY SCREEN AND DISPLAY DEVICE WITH THE FULL DISPLAY SCREEN

(71) Applicant: Wuhan China Star Optoelectronics Technology Co., Ltd., Wuhan (CN)

(72) Inventor: Sijie YANG, Wuhan (CN)

(21) Appl. No.: 16/316,050

(22) PCT Filed: Sep. 18, 2018
(86) PCT No.: PCT/CN2018/106409

§ 371 Date: Jan. 8, 2019

(51) Int. Cl. G02F 1/1345; H05K 1/18; G02F 1/13; G02F 1/1335

(52) U.S. Cl. CPC G02F 1/13458; G02F 1/13452; H05K 2201/10136; G02F 1/1309; G02F 1/133512; H05K 1/189

(57) ABSTRACT

The present invention provides a full display screen and a display device with the full display screen. The full display screen disposes at least one of a chip on film bonding welding pad and a cell forming test welding pad in a notch, which can realize a super narrow bottom bezel or even no bottom bezel, and can meet the requirements for the cell lighting test of the full display screen and making the qualification rate of bonding the chip onto the flexible circuit board be productive at the same time.

### BACKGROUND OF THE INVENTION

### Field of Invention

The present invention relates to field of liquid crystal display, and particularly to a full display screen and a display device with the full display screen.

### Description of Prior Art

At present, popularity of full-screen mobile phones gets higher and higher, and screens with a high screen occupation ratio become more and more popular. As a result, a lot of narrow bezel schemes mainly for left and right bezels are generated. But for mobile phones, it has been a big issue to increase the screen occupation ratio of bottom bezels. The so-called screen occupation ratio is a ratio between a screen area and an overall area, and a higher screen occupation ratio can bring better visual experience to users. Because of their high screen occupation ratio and good display effect, display of the full display screens becomes more and more popular and has become an inevitable trend for the future development of electronic devices such as the mobile phones. The full display screen is a relatively broad definition for the design of the mobile phones with the superhigh screen ratio in the mobile phone industry, which literally means that a front surface of the mobile phone is screen and positions of the mobile phone's four bezels are designed with no bezels, pursuing for a screen occupation ration of nearly 100%. However, due to the limitation of current technology, the full-screen mobile phone declared in industry is just the mobile phone with the superhigh occupation screen ratio for the time being, and the occupation screen ratio of its front surface can't make 100%. The full-screen mobile phone declared in industry is the mobile phone with an actual occupation screen ratio (which is not officially declared) of more than 80% and a super-narrow bezel design.

As the name indicates, chip on flexible printed circuit (COF) technology is a technology of making integrated circuit (IC) chips into flexible printed circuit (FPC). The COF technology is widely used in large panels, such as TV panels. Chip on glass (COG) technology is a technology of making IC chips into glass panels directly, and it's widely used in small-sized liquid crystal panels due to its advantage of saving FPC's material cost. However, with consumers' demands for narrow bezel mobile phones, disadvantages of the COG technology are increasingly prominent.

The COG technology must leave enough space out to install IC chips, which leads to a panel with a wide bezel and cannot realize the super narrow bezel design. To solve the problem of extremely narrow bezel, small panel makers began to take the COF technology into consideration.

Compared to the regular COG technology, the COF technology narrows the width of the bezels and increases the screen occupation ratio. For example, huawei P20 using a COG packaging process has a screen occupation ratio of 80.27%, while OPPO R15 using a COF packaging process has a higher screen occupation ratio of 90% than that of huawei P20. A bottom bezel using the COF packaging process can reduce 1.5 mm compared with that using the COG packaging process, thus improves the screen occupation ratio. The COF packaging process can reduce the width of the bottom bezel. Therefore, the bezel is reduced from the original 2.0 mm to 1.8 mm and then to 1.6 mm, and the limitation of the narrow bezel using the COF packaging process is also constantly broken.

### Technical Problems

The disadvantages of existing notch full display screen COF panels are:
(1) After the bottom bezel is constantly narrowed, the qualification rate of bonding a chip onto a flexible circuit board is reduced.
(2) In the COF packaging process, the size of cell test pad in the liquid crystal panel is greatly reduced when the width of the bottom bezel is 1.8 mm or 1.6 mm, which affects the cell lighting test and timing debugging of the liquid crystal panel.
(3) No matter the width of the bottom bezel is 1.8 mm or 1.6 mm, there's always a “chin”, which can't realize a same state of no bottom bezel like iphone X.

With the rapid development of the small and medium-sized electronic display industry, a requirement that notch full display screens put forward for the narrow bottom bezel is higher and higher in the COF packaging process, and it is better to realize no bottom bezel. At the same time, requirements for the cell lighting test of the liquid crystal panels and making the qualification rate of bonding the chip onto the flexible circuit board be productive also need to be met.

### SUMMARY OF THE INVENTION

A technical problem solved by the present disclosure is to provide a full display screen and a display device with the full display screen, which can realize a super narrow bottom bezel or even no bezel, and the requirements for the cell lighting test of the liquid crystal panel and making the qualification rate of bonding the chip onto the flexible circuit board realize a mass production need to be met at the same time.

For the above-mentioned objective, the present disclosure employs the following technical schemes.

A full display screen, comprising a display unit comprising a display area and a non-display area; a notch at a top end of the display area is arranged in the non-display area; the full display screen also comprises a chip on film bonding welding pad and a cell forming test welding pad; the chip on film bonding welding pad and the cell forming test welding pad are disposed in the non-display area; the chip on film bonding welding pad is disposed in the notch; the cell forming test welding pad is disposed in the non-display area at a bottom end of the display unit; the full display screen also comprises a functional component disposed in the notch.

A full display screen, comprising a display unit comprising a display area and a non-display area; a notch at a top end of the display area is arranged in the non-display area; the full display screen also comprises a chip on film bonding welding pad and a cell forming test welding pad; wherein the chip on film bonding welding pad and the cell forming test welding pad are disposed in the non-display area, and at least one of the chip on film bonding welding pad and the cell forming test welding pad is disposed in the notch.

In one exemplary embodiment, in the full display screen, the chip on film bonding welding pad is disposed in the notch; and the cell forming test welding pad is disposed in the non-display area at a bottom end of the display unit.

In one exemplary embodiment, in the full display screen, the cell forming test welding pad is disposed in the notch; and the chip on film bonding welding pad is disposed in the non-display area at a bottom end of the display unit.

In one exemplary embodiment, the full display screen also comprises a functional component; and the functional component is disposed in the notch.

In one exemplary embodiment, the full display screen also comprises a chip on film; the chip on film comprises a flexible circuit board, a bonding component and a driving chip; wherein the bonding component and the driving chip are disposed on a surface of the flexible circuit board; the flexible circuit board is connected to the chip on film bonding welding pad via the bonding component, and bent to a back surface of the display unit.

In one exemplary embodiment, the full display screen also comprises a glass cover plate, and the glass cover plate is disposed on a top surface of the display unit.

In one exemplary embodiment, in the full display screen, the glass cover plate comprises a light-shading layer; the light-shading layer is disposed in an area corresponding to the chip on film bonding welding pad and the cell forming test welding pad.

A display device, comprising the above full display screen and a backlight module disposed below the full display screen; an area of the display device, corresponding to the chip on film bonding welding pad and cell forming test welding pad, has no backlight emission.

In one exemplary embodiment, in the display device, an area of the backlight module, corresponding to the chip on film bonding welding pad and cell forming test welding pad is blocked by a light-shading layer.

In one exemplary embodiment, in the display device, an area of the backlight module, corresponding to the chip on film bonding welding pad and cell forming test welding pad has no backlight source.

The beneficial effect of the present disclosure is: the full display screen disposes at least one of the chip on film bonding welding pad and the cell forming test welding pad in the notch, which can realize a super narrow bottom bezel or even no bottom bezel, and can meet the requirements for the cell lighting test of the liquid crystal panels and making the qualification rate of bonding the chip onto the flexible circuit board be productive at the same time.

### BRIEF DESCRIPTION OF THE DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a planform of a full display screen according to a first exemplary embodiment of the present disclosure.

FIG. 2 is a structure diagram of a chip on film.

FIG. 3 is a planform of a full display screen according to a second exemplary embodiment of the present disclosure.

FIG. 4 is a planform of a full display screen according to a third exemplary embodiment of the present disclosure.

FIG. 5 is a structure diagram of a display device of the present disclosure.

### DETAILED DESCRIPTION OF THE PREFERRED EMBODIMENTS

The description of following embodiment, with reference to the attached drawings, is used to exemplify specific embodiments which may be carried out in the present disclosure.

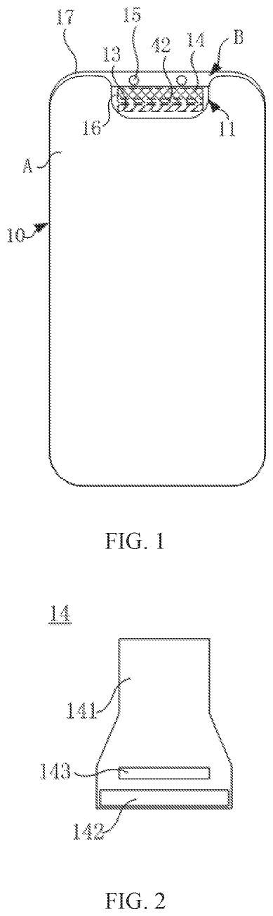

FIG. 1 is a planform of a full display screen according to a first exemplary embodiment of the present disclosure. Referring to FIG. 1, a full display screen 1 provided in the present disclosure comprises a display unit 10 comprising a display area A and a non-display area A, wherein the non-display area B may surround the display area A or may be disposed only above and/or below the display area A.

A notch 11 on a top end of the display area A is arranged in the non-display area B, that is, there are no images displayed in the notch 11. In the present disclosure, since the notch 11 is arranged in the non-display area B and the other areas of the display unit 10 except the notch 11 are all display area A, the full display screen 1 is a display screen with no bezels.

The full display screen 1 also comprises a chip on film bonding welding pad 12 and a cell forming test welding pad 13. The chip on film bonding welding pad 12 and the cell forming test welding pad 13 are disposed in the non-display area B, and at least one of them is disposed in the notch 11. Specifically speaking, in the first exemplary embodiment, the chip on film bonding welding pad 12 and the cell forming test welding pad 13 are all disposed in the notch 11.

The full display screen 1 also comprises a chip on film 14. FIG. 2 is a structure diagram of the chip on film 14. Referring to FIGS. 1 and 2, the chip on film 14 comprises a flexible circuit board 141, a bonding component 142 and a driving chip 143, wherein the bonding component 142 and the driving chip 143 are disposed on a surface of the flexible circuit board 141. The flexible circuit board 141 is connected to the chip on film bonding welding pad 12 via the bonding component 142. The flexible circuit board 141 is bent to a back surface of the display unit 10 and connected to a driving circuit (which is not shown out in the attached drawings) on the back surface of the display unit 10.

Wherein the full display screen 1 also comprises a functional component 15 disposed in the notch 11. The functional component includes but is not limited to a camera, sensor and other structure. The full display screen 1 also comprises a glass cover plate 17 disposed on a top surface of the display unit 10. The glass cover plate 17 covering the whole surface of the display unit 10. The glass cover plate 17 comprises a light-shading layer 16, and the light-shading layer 16 is disposed in an area corresponding to the chip on film bonding welding pad 12 and the cell forming test welding pad 13, in order to avoid the chip on film bonding welding pad 12 and the cell forming test welding pad 13 being exposed in a display surface of the display unit 10 and affecting the beauty of the full display screen 1. Since the chip on film bonding welding pad 12 and the cell forming test welding pad 13 are shielded by the light-shading layer 16, dotted lines in the attached drawings are used to depict the chip on film bonding welding pad 12 and the cell forming test welding pad 13.

In the first exemplary embodiment, the full display screen disposes both of the chip on film bonding welding pad 12 and the cell forming test welding pad 13 in the notch 11, and has no bottom bezel and side bezel, and has the non-display area B only in the notch 11, greatly increasing the screen occupation ratio of the full display screen. Moreover, because the chip on film bonding welding pad 12 and the cell forming test welding pad 13 are disposed in the notch 11 instead of a narrow bottom bezel, so the cell lighting test and the qualification rate of bonding the chip onto the flexible circuit board of the full display screen will not be affected.

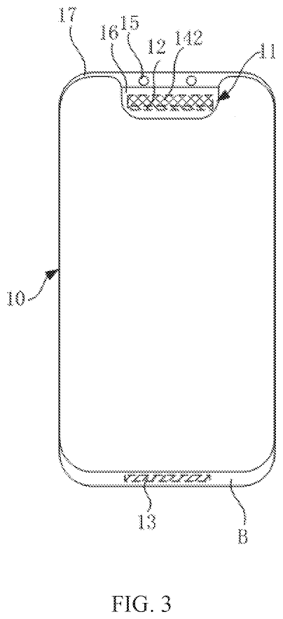

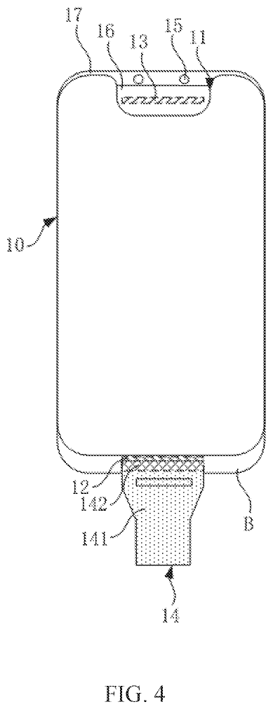

FIG. 3 is a planform of a full display screen according to a second exemplary embodiment of the present disclosure. Referring to FIGS. 2 and 3, in the second exemplary embodiment, the chip on film bonding welding pad 12 is disposed in the notch 11, and the cell forming test welding pad 13 is disposed in the non-display area B at a bottom end of the display unit 10, that is, the cell forming test welding pad 13 is disposed in the bottom bezel at the bottom end of the display unit 10. The flexible circuit board 141 of the chip on film is connected to the chip on film bonding welding pad 12 via the bonding component 142, and the flexible circuit board 141 of the chip on film 14 is bent to the back surface of the display unit 10 and connected to the driving circuit (which is not shown out in the attached drawings) on the back surface of the display unit 10.

Wherein the full display screen 1 also comprises the functional component 15 disposed in the notch 11. The functional component 15 includes but is not limited to a camera, sensor and other structure. The full display screen 1 also comprises the glass cover plate 17 disposed on the top surface of the display unit 10. The glass cover plate 17 covering the whole surface of the display unit 10. The glass cover plate 17 comprises the light-shading layer 16, and the light-shading layer 16 is disposed in the area corresponding to the chip on film bonding welding pad 12 and the cell forming test welding pad 13, in order to avoid the chip on film bonding welding pad 12 and the cell forming test welding pad 13 being exposed on the display surface of the display unit 10 and affecting the beauty of the full display screen 1.

In the second exemplary embodiment, the full display screen disposes the chip on film bonding welding pad 12 in the notch 11, and disposes the cell forming test welding pad 13 in the bottom bezel at the bottom end of the display unit 10, which can improve the problem that a narrow bottom bezel in the prior art affects the cell lighting test and the qualification rate of bonding the chip onto the flexible circuit board.

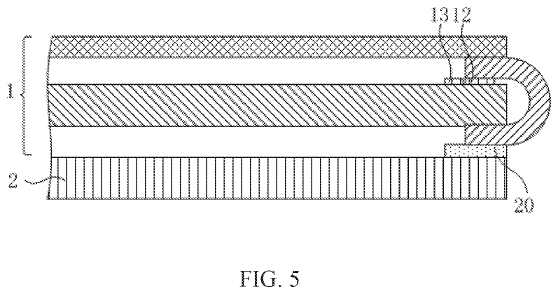

FIG. 4 is a planform of a full display screen according to a third exemplary embodiment of the present disclosure. Referring to FIG. 4, in a third exemplary embodiment, the cell forming test welding pad 13 is disposed in the notch 11, and the chip on film bonding welding pad 12 is disposed in the non-display area B at the bottom end of the display unit 10, that is, the chip on film bonding welding pad 12 is disposed in the bottom bezel at the bottom end of the display unit 10.

Wherein the flexible circuit board 141 of the chip on film 14 is connected to the chip on film bonding welding pad 12 via the bonding component 142. In FIG. 4, in order to show the relative relation between the chip on film 14 and the chip on film bonding welding pad 12, the chip on film 14 is schematically depicted, while in practice, the flexible circuit board 141 of the chip on film 14 is bent to the back surface of the display unit 10 and connected to the driving circuit (which is not shown out in the attached drawings) on the back surface of the display unit 10.

Wherein the full display screen 1 also comprises the functional component 15 disposed in the notch 11. The functional component 15 includes but is not limited to a camera, sensor and other structure. The full display screen 1 also comprises the glass cover plate 17 disposed on the top surface of the display unit 10. The glass cover plate 17 covering the whole surface of the display unit 10. The glass cover plate 17 comprises the light-shading layer 16, and the light-shading layer 16 is disposed in the area corresponding to the chip on film bonding welding pad 12 and the cell forming test welding pad 13, in order to avoid the chip on film bonding welding pad 12 and the cell forming test welding pad 13 being exposed on the display surface of the display unit 10 and affecting the beauty of the full display screen 1.

In the third exemplary embodiment, the full display screen disposes the cell forming test welding pad 13 in the notch 11, and disposes the chip on film bonding welding pad 12 in the bottom bezel at the bottom end of the display unit 10, which can improve the problem that the narrow bottom bezel in the prior art affects the cell lighting test and the qualification rate of bonding the chip onto the flexible circuit board.

FIG. 5 is a structure diagram of a display device of the present disclosure. Referring to FIG. 5, the display device comprises the above full display screen 1 and a backlight module 2 disposed below the full display screen 1. The full display screen 1 is characterized to display images, and the backlight module 2 is characterized to provide backlight. An area of the display device, corresponding to the chip on film bonding welding pad 12 and cell forming test welding pad 13, has no backlight emission. In the exemplary embodiment, a backlight area corresponding to the chip on film bonding welding pad 12 and cell forming test welding pad 13 is blocked by a light-shading layer 20, in order to make the area of the display device corresponding to the chip on film bonding welding pad 12 and cell forming test welding pad 13 has no backlight emission. Besides, in the other exemplary embodiments of the present disclosure, the backlight area corresponding to the chip on film bonding welding pad 12 and cell forming test welding pad 13 can has no backlight source when light sources are disposed in the backlight module 2, thus making the area of the display device corresponding to the chip on film bonding welding pad 12 and cell forming test welding pad 13 has no backlight emission.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

### INDUSTRIAL PRACTICABILITY

The theme of this application can be made and used in industry and has industrial practicability.

What is claimed is:

1. A full display screen, comprising:
a display unit comprising a display area and a non-display area; a notch at a top end of the display area is arranged in the non-display area;
a chip on film bonding welding pad and a cell forming test welding pad; the chip on film bonding welding pad and the cell forming test welding pad are disposed in the non-display area; the chip on film bonding welding pad is disposed in the notch;
the cell forming test welding pad is disposed in the non-display area at a bottom end of the display unit; and
a functional component disposed in the notch.

2. A full display screen, comprising:
a display unit comprising a display area and a non-display area; a notch at a top end of the display area is arranged in the non-display area;
a chip on film bonding welding pad and a cell forming test welding pad;
wherein the chip on film bonding welding pad and the cell forming test welding pad are disposed in the non-display area, and at least one of the chip on film bonding welding pad and the cell forming test welding pad is disposed in the notch.

3. The full display screen of claim 2, wherein the chip on film bonding welding pad is disposed in the notch; and the cell forming test welding pad is disposed in the non-display area at a bottom end of the display unit.

4. The full display screen of claim 2, wherein the cell forming test welding pad is disposed in the notch; and the chip on film bonding welding pad is disposed in the non-display area at a bottom end of the display unit.

5. The full display screen of claim 2, wherein the full display screen also comprises a functional component; and the functional component is disposed in the notch.

6. The full display screen of claim 2, wherein the full display screen also comprises a chip on film; the chip on film comprises a flexible circuit board, a bonding component and a driving chip; wherein the bonding component and the driving chip are disposed on a surface of the flexible circuit board; the flexible circuit board is connected to the chip on film bonding welding pad via the bonding component, and bent to a back surface of the display unit.

7. The full display screen of claim 2, wherein the full display screen also comprises a glass cover plate; and the glass cover plate is disposed on a top surface of the display unit.

8. The full display screen of claim 7, wherein the glass cover plate comprises a light-shading layer; the light-shading layer is disposed in an area corresponding to the chip on film bonding welding pad and the cell forming test welding pad.

9. A display device, comprising the full display screen of claim 2 and a backlight module disposed below the full display screen; an area of the display device, corresponding to the chip on film bonding welding pad and cell forming test welding pad, has no backlight emission.

10. The display device of claim 9, wherein an area of the backlight module, corresponding to the chip on film bonding welding pad and cell forming test welding pad is blocked by a light-shading layer.

11. The display device of claim 9, wherein an area of the backlight module, corresponding to the chip on film bonding welding pad and cell forming test welding pad has no backlight source.
